(19) United States
(12) Patent Application Publication
(10) Pub. No.: US 2026/0223386 A1
(43) Pub. Date: Jul. 30, 2026

(54) High Electron Mobility Transistor and Method for Manufacturing Same

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/074,144

(22) Filed: Mar. 7, 2025

Related U.S. Application Data
(60) Provisional application No. 63/749,202, filed on Jan. 24, 2025.

(51) Int. Cl. H10D 30/47; H10D 30/01; H10D 62/824

(52) U.S. Cl. CPC H10D 30/474; H10D 30/015; H10D 30/472; H10D 30/475; H10D 30/476; H10D 62/824

(57) ABSTRACT

A High-Electron-Mobility-Transistor comprising an upper insulating layer formed over a second buffer layer formed over a second barrier layer formed over a first buffer layer formed over a first barrier layer formed over a first doped structure and formed over a substrate. A second doped structure formed within the second barrier layer. A first gate electrode connected to the first doped structure. A second gate electrode connected to the second doped structure. A drain terminal formed at a first side of the first gate electrode. A source terminal formed at a second side of the first gate electrode.

### CROSS-REFERENCE TO RELATED APPLICATION

The present application claims priority to U.S. Provisional Patent Application No. 63/749,202 filed on Jan. 24, 2025, the contents of which are hereby incorporated by reference in their entirety.

### TECHNICAL FIELD

The present disclosure relates high electron mobility transistors (HEMTs), and more specifically to high performance HEMTs and methods for manufacturing same to improve the drive current and to reduce the leakage current of the HEMT.

### SUMMARY

According to an aspect of one or more examples, there is provided a High-Electron-Mobility-Transistor that may include a substrate, a first doped structure formed within the substrate, a first barrier layer formed over the first doped structure and formed over the substrate, a first buffer layer formed over the first barrier layer, a second barrier layer formed over the first buffer layer, a second doped structure formed within the second barrier layer, a second buffer layer formed over the second barrier layer, an upper insulating layer formed over the second buffer layer, a first spacer formed on a portion of the first doped structure through the first barrier layer, through the first buffer layer, through the second barrier layer, through the second buffer layer and through the upper insulating layer, a first gate electrode formed within the first spacer through the upper insulating layer, through the second buffer layer, through the second barrier layer, through the first buffer layer, through the first barrier layer, the first gate electrode connected to the first doped structure, a second spacer formed on a portion of the second doped structure partially through an upper portion of the second barrier layer, through the second buffer layer and through the upper insulating layer, a second gate electrode formed within the second spacer through the upper insulating layer, through the second buffer layer and partially into the upper portion of the second barrier layer, the second gate electrode connected to the second doped structure, a drain terminal formed at a first side of the first gate electrode, and a source terminal formed at a second side of the first gate electrode. The first doped structure may be insulated from the substrate by a lower insulating layer. The first buffer layer may comprise a first III-V compound semiconductor such as gallium nitride. The second buffer layer may comprise a first III-V compound semiconductor such as gallium nitride. The first barrier layer and the second barrier layer may comprise aluminum gallium nitride. The first doped structure may comprise P-doped gallium nitride. The second doped structure may comprise P-doped gallium nitride. The upper insulating layer may comprise polysilicon, silicon dioxide or a mixture of polysilicon and silicon dioxide. The lower insulating layer may comprise polysilicon, silicon dioxide or a mixture of polysilicon and silicon dioxide.

According to an aspect of one or more examples, there is provided method for producing a High-Electron-Mobility-Transistor. The method may include providing a substrate, forming a first doped structure within the substrate, forming a first barrier layer over the first doped structure and over the substrate, forming a first buffer layer over the first barrier layer, forming a second barrier layer over the first buffer layer, forming a second doped structure within the second barrier layer, forming a second buffer layer over the second barrier layer, forming an upper insulating layer over the second buffer layer, forming a first spacer on a portion of the first doped structure through the first barrier layer, through the first buffer layer, through the second barrier layer, through the second buffer layer and through the upper insulating layer, forming a first gate electrode within the first spacer through the upper insulating layer, through the second buffer layer, through the second barrier layer, through the first buffer layer, through the first barrier layer, the first gate electrode connected to the first doped structure, forming a second spacer on a portion of the second doped structure partially through an upper portion of the second barrier layer, through the second buffer layer and through the upper insulating layer, forming a second gate electrode within the second spacer through the upper insulating layer, through the second buffer layer and partially into the upper portion of the second barrier layer, the second gate electrode connected to the second doped structure, forming a drain terminal at a first side of the first gate electrode, and forming a source terminal at a second side of the first gate electrode. The first doped structure may be insulated from the substrate by a lower insulating layer. The first buffer layer may comprise a first III-V compound semiconductor such as gallium nitride. The second buffer layer may comprise a first III-V compound semiconductor such as gallium nitride. The first barrier layer and the second barrier layer may comprise aluminum gallium nitride. The first doped structure may comprise P-doped gallium nitride. The second doped structure may comprise P-doped gallium nitride. The upper insulating layer may comprise polysilicon, silicon dioxide or a mixture of polysilicon and silicon dioxide. The lower insulating layer may comprise polysilicon, silicon dioxide or a mixture of polysilicon and silicon dioxide.

### BRIEF DESCRIPTION OF DRAWINGS

FIG. 1A is a cross sectional view of a High-Electron-Mobility-Transistor according to one or more examples;

FIG. 1B is a top view of a High-Electron-Mobility-Transistor according to one or more examples;

FIG. 2A is cross sectional view of some of the steps in a method of manufacturing a High-Electron-Mobility-Transistor according to one or more examples;

FIG. 2B is cross sectional view of some of the steps in a method of manufacturing a High-Electron-Mobility-Transistor according to one or more examples;

FIG. 2C is cross sectional view of some of the steps in a method of manufacturing a High-Electron-Mobility-Transistor according to one or more examples;

FIG. 2D is cross sectional view of some of the steps in a method of manufacturing a High-Electron-Mobility-Transistor according to one or more examples;

FIG. 2E is cross sectional view of some of the steps in a method of manufacturing a High-Electron-Mobility-Transistor according to one or more examples; and

FIG. 2F is cross sectional view of some of the steps in a method of manufacturing a High-Electron-Mobility-Transistor according to one or more examples.

FIG. 2G is cross sectional view of some of the steps in a method of manufacturing a High-Electron-Mobility-Transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

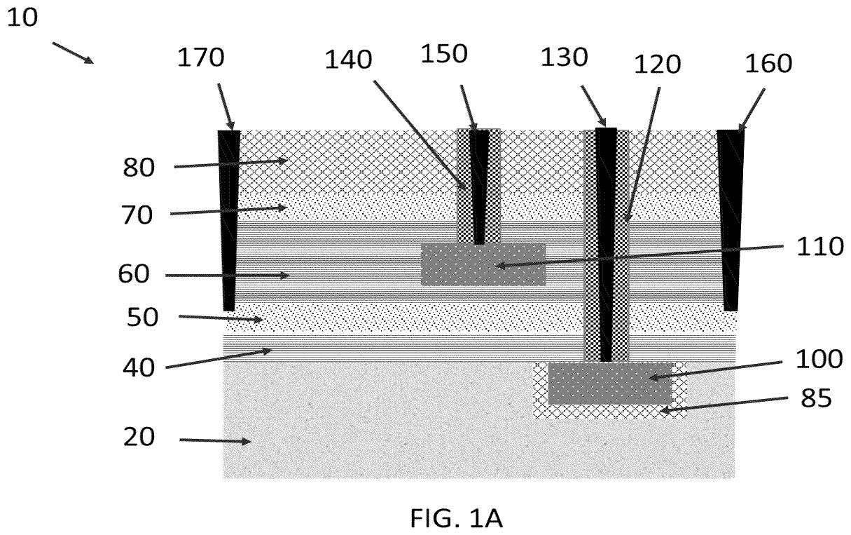

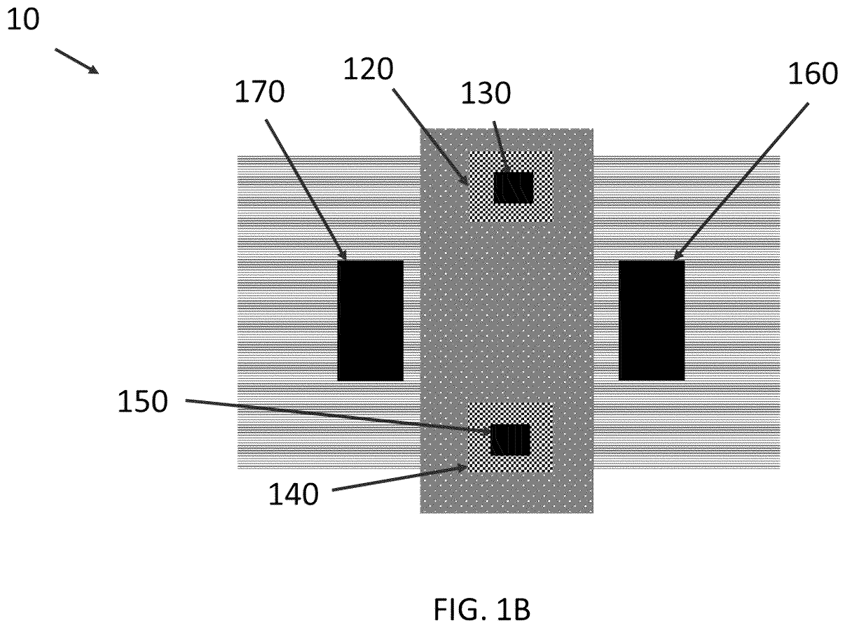

FIG. 1A shows a cross sectional view of a High-Electron-Mobility-Transistor 10 according to one or more examples. As shown in FIG. 1, the High-Electron-Mobility-Transistor 10, has a substrate 20 with a first doped structure 100 within the substrate 20. The first doped structure 100 may comprise P-doped gallium nitride. The first doped structure 100 may be insulated from the substrate 20 by a lower insulating layer 85. The lower insulating layer 85 may comprise polysilicon, silicon dioxide or a mixture of polysilicon and silicon dioxide or any other insulating material or a mixture of all these. The substrate 20 may comprise gallium nitride, diamond, silicon carbide, sapphire, aluminum nitride or silicon. A first barrier layer 40 may be formed over the first doped structure 100 and formed over the substrate 20. The first barrier layer 40 may comprise aluminum gallium nitride. A first buffer layer 50 may be formed over the first barrier layer 40. The first buffer layer 50 may comprise a first III-V compound semiconductor such as gallium nitride. A second barrier layer 60 may be formed over the first buffer layer 50. The second barrier layer 60 may comprise aluminum gallium nitride. A second doped structure 110 may be formed within the second barrier layer 60. The second doped structure 110 may comprise P-doped gallium nitride. A second buffer layer 70 may be formed over the second barrier layer 60. The second buffer layer 70 may comprise a second III-V compound semiconductor such as gallium nitride. Due to the nature of gallium nitride/aluminum gallium nitride band bending a 2DEG (Two-Dimensional Electron Gas) may be formed at the interfaces of these two materials (the first buffer layer 50 and the first barrier layer 40, the first buffer layer 50 and the second barrier layer 60, and the second buffer layer 70 and the second barrier layer 60). This is like electron gas that is free to move in 2 dimensions and confined in the third dimension. An upper insulating layer 80 may be formed over the second buffer layer 70. The upper insulating layer 80 may comprise polysilicon, silicon dioxide or a mixture of polysilicon and silicon dioxide or any other insulating material or a mixture of all these. A first spacer 120 may be formed on a portion of the first doped structure 100 through the first barrier layer 40, through the first buffer layer 50, through the second barrier layer 60, through the second buffer layer 70 and through the upper insulating layer 80. A first gate electrode 130 may be formed within the first spacer 120 through the upper insulating layer 80, through the second buffer layer 70, through the second barrier layer 60, through the first buffer layer 50, through the first barrier layer 40. The first gate electrode 130 may be connected to the first doped structure 100. A second spacer 140 may be formed on a portion of the second doped structure 110 partially through an upper portion of the second barrier layer 60, through the second buffer layer 70 and through the upper insulating layer 80. A second gate electrode 150 may be formed within the second spacer 140 through the upper insulating layer 80, through the second buffer layer 70 and partially into the upper portion of the second barrier layer 60. The second gate electrode 150 may be connected to the second doped structure 110. In FIG. 1A, the second gate electrode 150 is shown laterally shifted to the first gate electrode 130 since this is a two dimensional drawing. However, in most cases, the second gate electrode 150 is in alignment with the first gate electrode 130. In addition, the first gate electrode 130 can be shorted to the second gate electrode 150 so that there is a single gate electrode. Alternatively, the first gate electrode 130 may operate independent of the second gate electrode 150. A drain terminal 160 may be formed at a first side of the first gate electrode 130. A source terminal 170 may be formed at a second side of the first gate electrode 130.

FIG. 1B shows a top view of a High-Electron-Mobility-Transistor 10 according to one or more examples. As shown in FIG. 1B, the High-Electron-Mobility-Transistor 10 may have a first spacer 120 with a first gate electrode 130 that may be formed within the first spacer 120. As shown in FIG. 1B, the High-Electron-Mobility-Transistor 10 may have a second spacer 140 with a second gate electrode 150 that may be formed within the second spacer 140. A drain terminal 160 may be formed at a first side of the first gate electrode 130. A source terminal 170 may be formed at a second side of the first gate electrode 130.

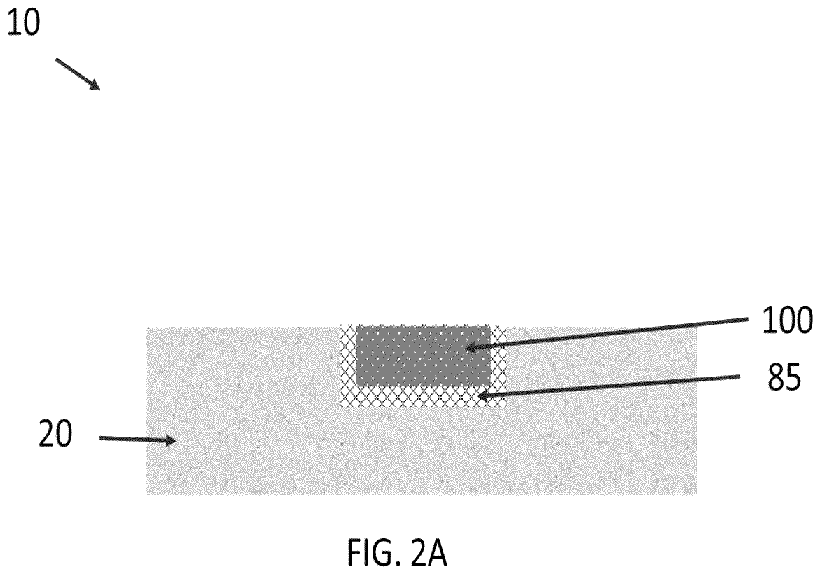

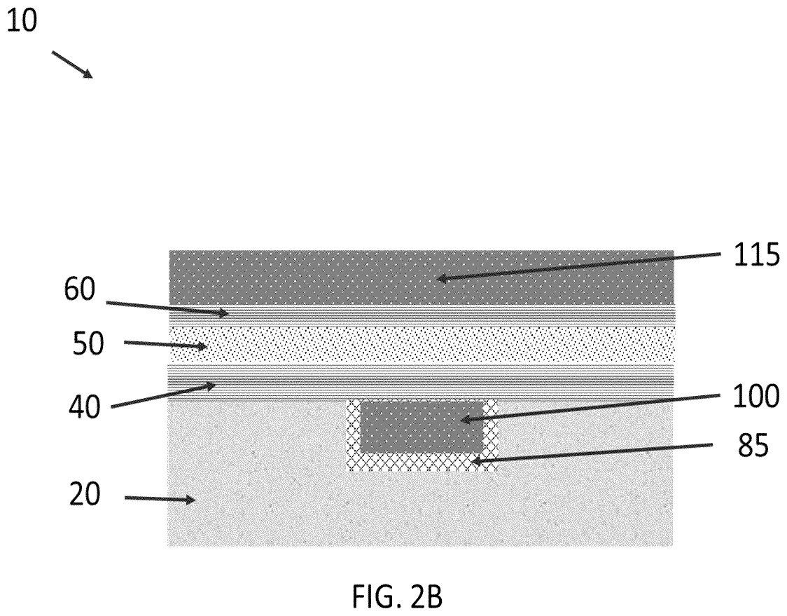

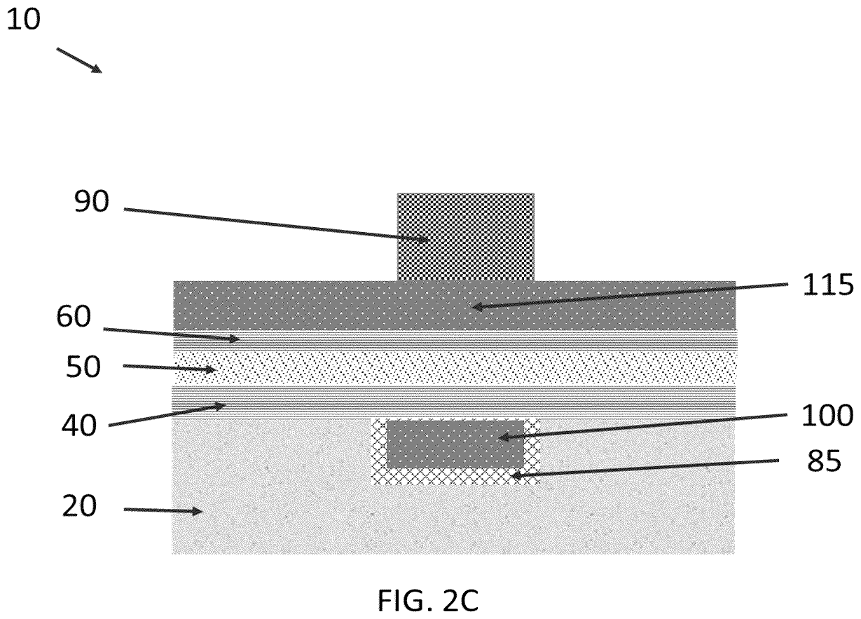

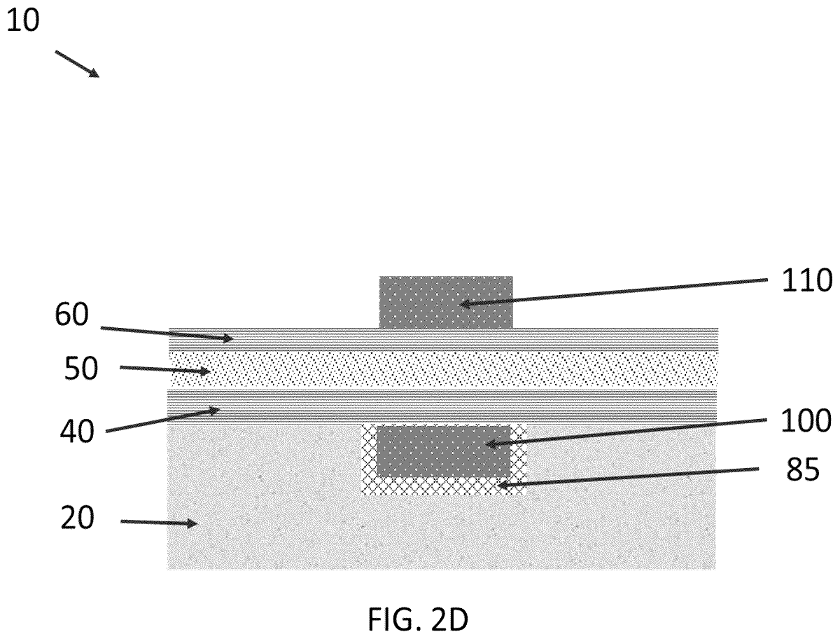

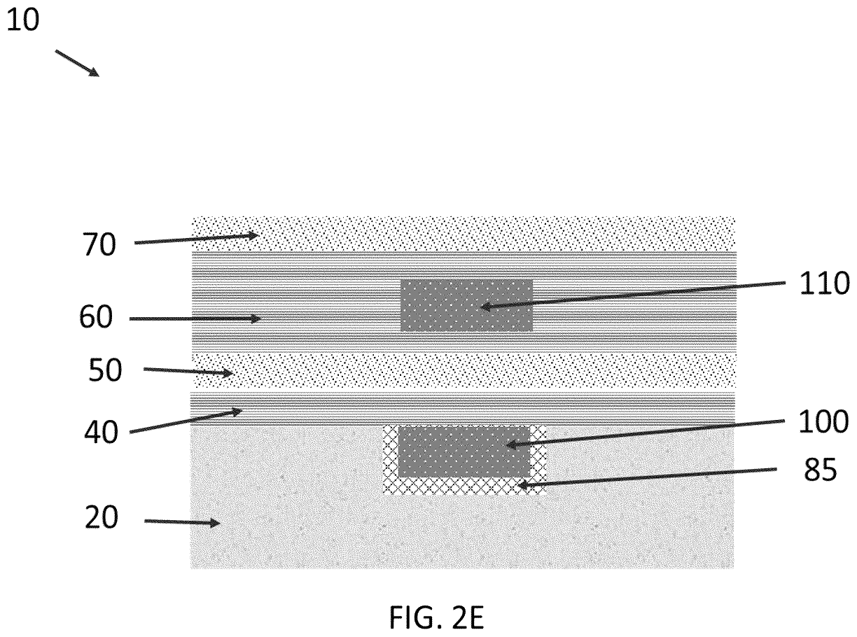

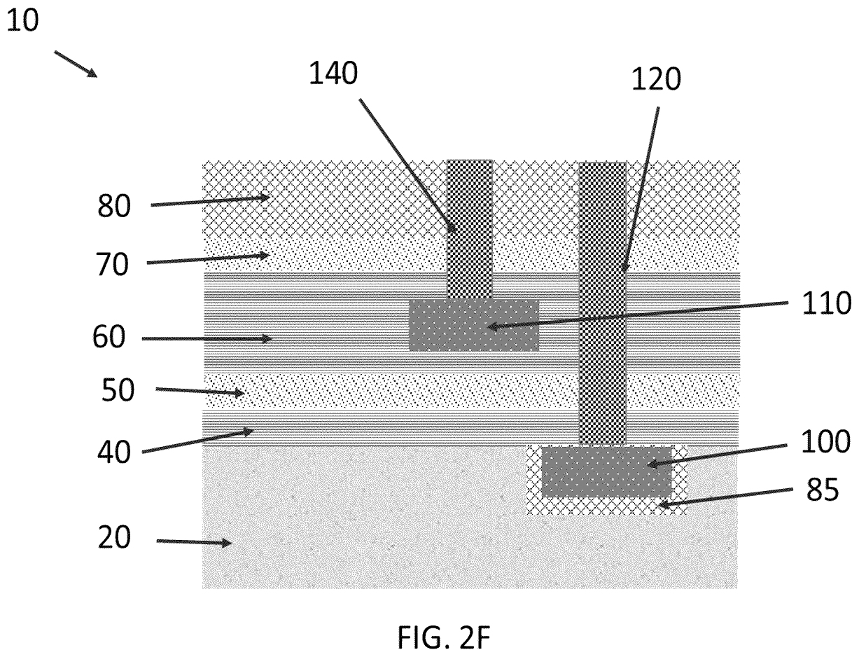

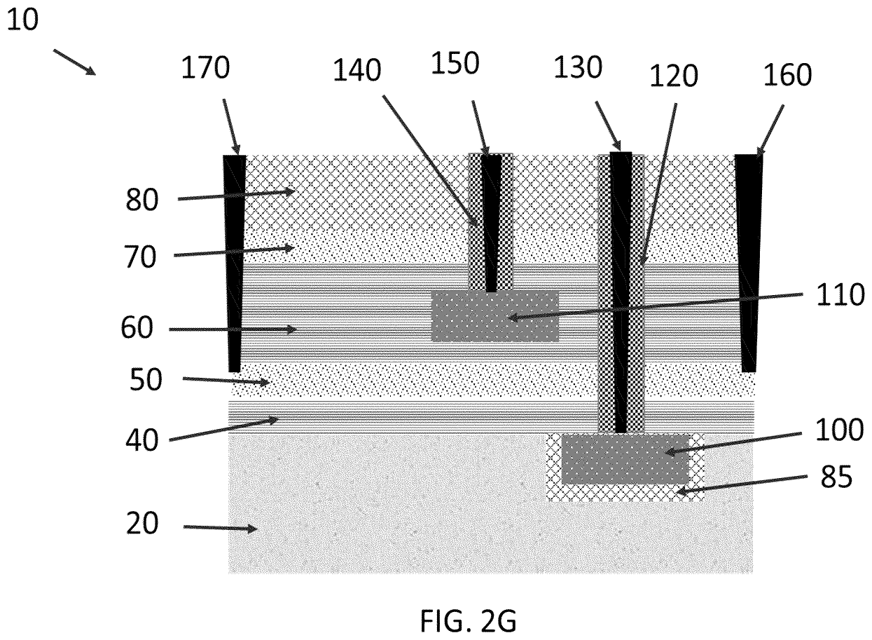

FIGS. 2A-2G show a method of manufacturing a High-Electron-Mobility-Transistor 10 according to one or more example. Although the example method shown in FIGS. 2A-2G includes steps shown in a particular order, the steps may be performed in a different order, and may include additional steps that are not explicitly shown. In addition, each step presented herein may have multi-steps necessary to carry out the stated step that are not explicitly shown or stated herein.

FIG. 2A is cross sectional view of some of the steps in a method of manufacturing a High-Electron-Mobility-Transistor 10 according to one or more examples. In FIG. 2A, the example method may include forming a first doped structure 100 within a substrate 20. The substrate 20 may comprise gallium nitride, diamond, silicon carbide, sapphire, aluminum nitride or silicon. The first doped structure 100 may comprise P-doped gallium nitride. The first doped structure 100 may be insulated from the substrate by a lower insulating layer 85. The lower insulating layer 85 may comprise polysilicon, silicon dioxide or a mixture of polysilicon and silicon dioxide or any other insulating material or a mixture of all these.

FIG. 2B is cross sectional view of some of the steps in a method of manufacturing a High-Electron-Mobility-Transistor 10 according to one or more examples. FIG. 2B shows the formation of a first barrier layer 40 over the first doped structure 100 and over the substrate 20. The first barrier layer 40 may comprise aluminum gallium nitride. A first buffer layer 50 may be formed over the first barrier layer 40. The first buffer layer 50 may comprise a first III-V compound semiconductor such as gallium nitride. A second barrier layer 60 may be formed over the first buffer layer 50. The second barrier layer 60 may comprise aluminum gallium nitride. A doped layer 115 may be formed over the second barrier layer 60. The doped layer 115 may comprise P-doped gallium nitride.

FIG. 2C is cross sectional view of some of the steps in a method of manufacturing a High-Electron-Mobility-Transistor 10 according to one or more examples. FIG. 2C shows the formation of a gate mask 90 that may be formed over the doped layer 115.

FIG. 2D is cross sectional view of some of the steps in a method of manufacturing a High-Electron-Mobility-Transistor 10 according to one or more examples. FIG. 2D shows the patterning of the doped layer 115 into a second doped structure 110.

FIG. 2E is cross sectional view of some of the steps in a method of manufacturing a High-Electron-Mobility-Transistor 10 according to one or more examples. FIG. 2E includes depositing or epitaxially growing additional second barrier layer 60 onto a top surface of the second doped structure 110 and onto side surfaces of the second doped structure 110 to completely surround the second doped structure 110. FIG. 2E includes forming a second buffer layer 70 over the second barrier layer 60. The second buffer layer 70 may comprise a second III-V compound semiconductor such as gallium nitride.

FIG. 2F is cross sectional view of some of the steps in a method of manufacturing a High-Electron-Mobility-Transistor 10 according to one or more examples. FIG. 2F shows the formation of an upper insulating layer 80 that may be formed over the second buffer layer 70. The upper insulating layer 80 may comprise polysilicon, silicon dioxide or a mixture of polysilicon and silicon dioxide or any other insulating material or a mixture of all these. FIG. 2F shows the formation of a first spacer 120 that may be formed on a portion of the first doped structure 100 through the first barrier layer 40, through the first buffer layer 50, through the second barrier layer 60, through the second buffer layer 70 and through the upper insulating layer 80. FIG. 2F shows the formation of a second spacer 140 that may be formed on a portion of the second doped structure 110 partially through an upper portion of the second barrier layer 60, through the second buffer layer 70 and through the upper insulating layer 80.

FIG. 2G is cross sectional view of some of the steps in a method of manufacturing a High-Electron-Mobility-Transistor 10 according to one or more examples. FIG. 2G shows the formation of a first gate electrode 130 that may be formed within the first spacer 120 through the upper insulating layer 80, through the second buffer layer 70, through the second barrier layer 60, through the first buffer layer 50, through the first barrier layer 40. The first gate electrode 130 may be connected to the first doped structure 100. FIG. 2G shows the formation of a second gate electrode 150 that may be formed within the second spacer 140 through the upper insulating layer 80, through the second buffer layer 70 and partially into the upper portion of the second barrier layer 60. The second gate electrode 150 may be connected to the second doped structure 110. In FIG. 2G, the second gate electrode 150 is shown laterally shifted to the first gate electrode 130 since this is a two dimensional drawing. However, in most cases, the second gate electrode 150 is in alignment with the first gate electrode 130. In addition, the first gate electrode 130 may be shorted to the second gate electrode 150 so that there is a single gate electrode. Alternatively, the first gate electrode 130 can operate independent of the second gate electrode 150. A drain terminal 160 may be formed at a first side of the first gate electrode 130. A source terminal 170 may be formed at a second side of the first gate electrode 130. Due to the nature of gallium nitride/aluminum gallium nitride band bending a 2DEG (Two-Dimensional Electron Gas) is formed at the interfaces of these two materials (the first buffer layer 50 and the first barrier layer 40, the first buffer layer 50 and the second barrier layer 60, and the second buffer layer 70 and the second barrier layer 60). This is like electron gas that is free to move in 2 dimensions and confined in the third dimension.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A High-Electron-Mobility-Transistor comprising:
a substrate;
a first doped structure formed within the substrate;
a first barrier layer formed over the first doped structure and formed over the substrate;
a first buffer layer formed over the first barrier layer;
a second barrier layer formed over the first buffer layer;
a second doped structure formed within the second barrier layer;
a second buffer layer formed over the second barrier layer;
an upper insulating layer formed over the second buffer layer;
a first spacer formed on a portion of the first doped structure through the first barrier layer, through the first buffer layer, through the second barrier layer, through the second buffer layer and through the upper insulating layer;
a first gate electrode formed within the first spacer through the upper insulating layer, through the second buffer layer, through the second barrier layer, through the first buffer layer, through the first barrier layer, the first gate electrode connected to the first doped structure;
a second spacer formed on a portion of the second doped structure partially through an upper portion of the second barrier layer, through the second buffer layer and through the upper insulating layer;
a second gate electrode formed within the second spacer through the upper insulating layer, through the second buffer layer and partially into the upper portion of the second barrier layer, the second gate electrode connected to the second doped structure;
a drain terminal formed at a first side of the first gate electrode; and
a source terminal formed at a second side of the first gate electrode.

2. The High-Electron-Mobility-Transistor of claim 1, wherein the first doped structure insulated from the substrate by a lower insulating layer.

3. The High-Electron-Mobility-Transistor of claim 1, wherein the first buffer layer comprises a first III-V compound semiconductor.

4. The High-Electron-Mobility-Transistor of claim 3, wherein the second buffer layer comprises a first III-V compound semiconductor.

5. The High-Electron-Mobility-Transistor of claim 4, wherein the first buffer layer and the second buffer layer comprise gallium nitride.

6. The High-Electron-Mobility-Transistor of claim 1, wherein the first barrier layer and the second barrier layer comprise aluminum gallium nitride.

7. The High-Electron-Mobility-Transistor of claim 1, wherein the first doped structure comprises P-doped gallium nitride.

8. The High-Electron-Mobility-Transistor of claim 7, wherein the second doped structure comprises P-doped gallium nitride.

9. The High-Electron-Mobility-Transistor of claim 1, wherein the upper insulating layer comprises polysilicon, silicon dioxide or a mixture of polysilicon and silicon dioxide.

10. The High-Electron-Mobility-Transistor of claim 2, wherein the lower insulating layer comprises polysilicon, silicon dioxide or a mixture of polysilicon and silicon dioxide.

11. A method for producing a High-Electron-Mobility-Transistor comprising:
providing a substrate;
forming a first doped structure within the substrate;
forming a first barrier layer over the first doped structure and over the substrate;
forming a first buffer layer over the first barrier layer;
forming a second barrier layer over the first buffer layer;
forming a second doped structure within the second barrier layer;
forming a second buffer layer over the second barrier layer;
forming an upper insulating layer over the second buffer layer;
forming a first spacer on a portion of the first doped structure through the first barrier layer, through the first buffer layer, through the second barrier layer, through the second buffer layer and through the upper insulating layer;
forming a first gate electrode within the first spacer through the upper insulating layer, through the second buffer layer, through the second barrier layer, through the first buffer layer, through the first barrier layer, the first gate electrode connected to the first doped structure;
forming a second spacer on a portion of the second doped structure partially through an upper portion of the second barrier layer, through the second buffer layer and through the upper insulating layer;
forming a second gate electrode within the second spacer through the upper insulating layer, through the second buffer layer and partially into the upper portion of the second barrier layer, the second gate electrode connected to the second doped structure;
forming a drain terminal at a first side of the first gate electrode; and
forming a source terminal at a second side of the first gate electrode.

12. The method for producing a High-Electron-Mobility-Transistor of claim 11, wherein the first doped structure insulated from the substrate by a lower insulating layer.

13. The method for producing a High-Electron-Mobility-Transistor of claim 11, wherein the first buffer layer comprises a first III-V compound semiconductor.

14. The method for producing a High-Electron-Mobility-Transistor of claim 13, wherein the second buffer layer comprises a first III-V compound semiconductor.

15. The method for producing a High-Electron-Mobility-Transistor of claim 14, wherein the first buffer layer and the second buffer layer comprise gallium nitride.

16. The method for producing a High-Electron-Mobility-Transistor of claim 11, wherein the first barrier layer and the second barrier layer comprise aluminum gallium nitride.

17. The method for producing a High-Electron-Mobility-Transistor of claim 11, wherein the first doped structure comprises P-doped gallium nitride.

18. The method for producing a High-Electron-Mobility-Transistor of claim 17 doped structure comprises P-doped gallium nitride.

19. The method for producing a High-Electron-Mobility-Transistor of claim 11, wherein the upper insulating layer comprises polysilicon, silicon dioxide or a mixture of polysilicon and silicon dioxide.

20. The method for producing a High-Electron-Mobility-Transistor of claim 12, wherein the lower insulating layer comprises polysilicon, silicon dioxide or a mixture of polysilicon and silicon dioxide.
